(19) United States
(12) Patent Application Publication
(10) Pub. No.: US 2006/0166523 A1
(43) Pub. Date: Jul. 27, 2006

(54) Plug-type connection for a ribbon conductor

(75) Inventors: Ulf Bartholomaeus, St. Georgen (DE); Markus Bilger, Trossingen (DE); Josef Rottler, Koenigsfeld (DE); Klaus Umfahrer, Stuttgart (DE); Mathias Vollmer, Villingen-Schwenningen (DE)

Correspondence Address: SIEMENS SCHWEIZ;I-44, INTELLECTUAL PROPERTY, ALBISRIEDERSTRASSE 245, ZURICH, CH-8047, CH

(73) Assignee: Siemens Aktiengesellschaft, Munich (DE)

(21) Appl. No.: 10/545,903

(22) PCT Filed: Feb. 16, 2004
(86) PCT No.: PCT/EP04/01445

§ 371 Date: Aug. 17, 2005

(30) Foreign Application Priority Data
Feb. 19, 2003 (DE) 103 07 076.1

(51) Int. Cl. H05K 1/00

(52) U.S. Cl. 439/67

(57) ABSTRACT

The invention relates to a plug-type connection in which a ribbon cable (1) is inserted into a plug (3). According to the invention, the ribbon cable (1) has a marking (2).

The invention relates to a plug-type connection between a ribbon cable and a plug suitable for ribbon cables. In the prior art, plug-type apparatuses are known in which ribbon cables can be inserted into plugs without being locked in This takes place in particular manually, since it is only possible to check for a correct contact-connection automatically using electrical means.

It is therefore the object of the invention to specify a plug-type connection which can also be carried out automatically and in which inspection of the electrical contact can be dispensed with. This object is achieved by the ribbon cable being provided with a marker. Once the ribbon cable has been mounted in the plug, it is possible for the position of the marker in relation to the plug to be inspected visually and to thereby establish whether the ribbon cable has been mounted correctly. In particular, the marker may be in the form of a marker line which in a particularly advantageous manner extends at a right angle to the extent of the ribbon cable. It is thus possible for the distance between the marker line and the plug to be measured.

The invention will be explained in more detail below with reference to the figures, in which:

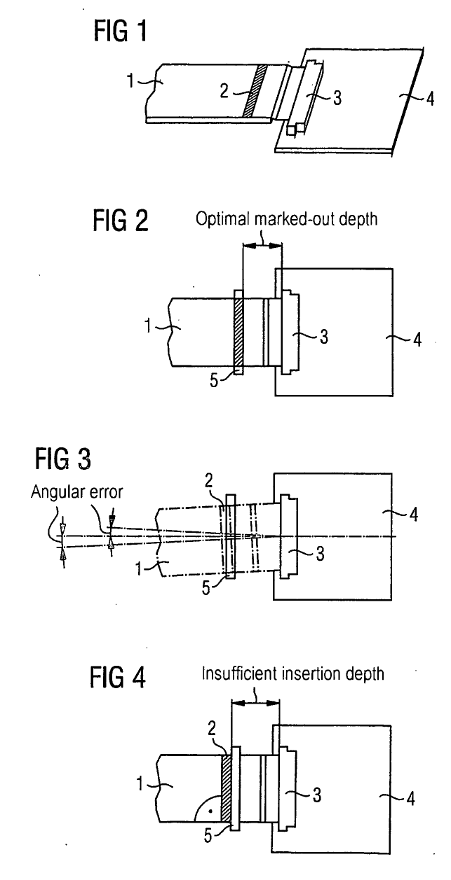

FIG. 1 shows a ribbon cable having a marker in a plug,

FIG. 2 shows the plan view of the group of components shown in FIG. 1, an optimal marked-out depth being illustrated,

FIG. 3 shows a plan view of the assembly shown in FIG. 1 in which an angular error has occurred, and

FIG. 4 shows the plan view of the assembly shown in FIG. 1, the ribbon cable having been inserted to an insufficient extent.

FIG. 1 shows a ribbon cable 1 having a marker 2 and also a plug 3 which is arranged on a printed circuit board 4 and is electrically connected to said printed circuit board 4. There is a high contrast between the marker 2 and the flexible conductor 1. In particular, in the case of light-colored flexible conductors, a black marker is particularly suitable.

FIGS. 2 to 4 also illustrate a sensor array 5 of a test device which is otherwise not illustrated. As long as the sensor array 5 coincides with the marker 2, an optimal marked-out depth of the ribbon cable can be assumed.

In FIG. 3, an angular error is detected since only parts of the sensor array 5 are covered.

In FIG. 4, an insufficient insertion depth is established since the sensor array 5 has not yet detected the marker 2.

The marker 2 may be of any desired form; it is therefore in particular also possible for colored markers to be provided only at the edges of the ribbon cable. It is also possible for the markers to be in three-dimensional form using, for example, strips or notches. However, overall it has been shown that an optical marker in the form of a continuous line can be inspected particularly easily and reliably.

The ribbon cable may have, for example, a contact pitch of 0.3 mm, 0.5 mm, 1 mm or 1.25 mm.

1. (canceled)

2. (canceled)

3. (canceled)

4. (canceled)

5. A plug-type connection, comprising means for receiving a ribbon cable is inserted into the plug, the plug being arranged on a printed circuit board and being electrically connected to the printed circuit board, wherein the ribbon cable comprises a marker.

6. The plug-type connection according to claim 5, wherein the marker is a marker line.

7. The plug-type connection according to claim 2, wherein the marker line extends at substantially right angles to the extent of the ribbon cable.

8. The plug-type connection according to claim 1, wherein marker color is in contrast to the rest of the ribbon cable.
